(19) United States
(12) Patent Application Publication
(10) Pub. No.: US 2025/0301592 A1
(43) Pub. Date: Sep. 25, 2025

(54) MULTIFUNCTIONAL INTELLIGENT CALENDAR

(71) Applicant: Shenzhen Joyhong Tech Co.,Ltd, Shenzhen (CN)

(72) Inventor: Jianping Wang, Shenzhen (CN)

(21) Appl. No.: 19/231,439

(22) Filed: Jun. 7, 2025

(30) Foreign Application Priority Data
May 13, 2025 (CN) 202510613913.9

(51) Int. Cl. H05K 7/14; H05K 5/03; H05K 9/00

(52) U.S. Cl. CPC H05K 7/1427; H05K 5/03; H05K 9/002

(57) ABSTRACT

A multifunctional intelligent calendar is provided, which includes an intelligent electronic calendar body and a magnetic attraction mechanism. A detachable shell covers the back of the intelligent electronic calendar body; the magnetic attraction mechanism includes magnetic attraction components located on an inner side and an outer side of the shell. In this way, the calendar is magnetically fixed, so that the calendar can be easily adsorbed on a surface such as a wall and a metal object, and can be stably fixed on an inclined surface, at a side-hanging position, or at a ceiling-mounted suspending position, which greatly expands use scenes of the intelligent calendar and effectively ensures practical functionality of the intelligent calendar.

### TECHNICAL FIELD

The present disclosure relates to the technical field of intelligent calendars, and in particular to a multifunctional intelligent calendar.

### BACKGROUND

With the popularity of an intelligent device, an intelligent calendar has gradually become an important tool for managing time and events in daily lives of people. Most of the existing intelligent calendars focus on functions of recording schedules and travel plans, as well as storing and viewing pictures and electronic documents, etc. However, the existing intelligent calendars have obvious limitations on use scenes, and can only be placed on a surface of a horizontal object with a support such as a table and a cabinet. A use area is basically limited to a conventional space such as a bedroom, a study, and a living room. The manner of restricting space usage makes it impossible for the intelligent calendar to meet needs of users in diverse scenes such as a kitchen, a bathroom, a balcony, a doorway, a vehicle or outdoors, and it is also difficult to achieve personalized placement and decoration effects.

Moreover, in real life, due to the differences in ideas, lifestyles and behavior habits of different users, more and more people hope that an intelligent calendar can break through the constraints of existing placement methods and use areas. However, a conventional intelligent calendar cannot be placed in an unconventional position such as an inclined surface, a side-hanging position, or a ceiling-mounted position, which cannot make full use of space and cannot meet the needs of users for personalized decoration of an intelligent device. Therefore, it is of high practicability to provide a multifunctional intelligent calendar that is capable of being magnetically fixed.

### SUMMARY

The objective of the present disclosure is to provide a multifunctional intelligent calendar, so as to solve the problems raised in the foregoing background.

In order to achieve the above objective, the present disclosure provides the following technical solution. A multifunctional intelligent calendar is provided, which includes an intelligent electronic calendar body and a magnetic attraction mechanism. A detachable shell covers the back of the intelligent electronic calendar body. The magnetic attraction mechanism includes magnetic attraction components located on an inner side and an outer side of the shell. The magnetic attraction component magnetically attracts a magnetic attraction plate located outside the shell. A magnetic back plate is magnetically adsorbed on an outer side of the magnetic attraction plate. A calendar body is suspended and fixed after the magnetic back plate is adsorbed with a magnetic object or a metal object. Each layer of the magnetic attraction components includes at least one magnet. The magnets of two layers of the magnetic attraction components are oppositely arranged in position and connected by magnetic non-contact adsorption. The magnets located on an outer side are flush-embedded in a first groove provided on the outer side of the magnetic attraction plate.

As a preferred solution of the present disclosure, the magnets located on an inner side are flush-embedded in a second groove provided on the inner side of the shell, and a position of the first groove is opposite to that of the second groove.

As a preferred solution of the present disclosure, a plurality of magnets of the magnetic attraction components are distributed in a linear, triangular, rectangular, circular or polygonal array on the inner side and the outer side of the shell.

As a preferred solution of the present disclosure, the magnet is one or more of a triangle, a circle, a rectangle or a polygon, and a thickness of the magnet is the same as groove depths in the first groove and the second groove.

As a preferred solution of the present disclosure, a metal shielding cover is arranged on the inner side of the shell at a position opposite to a circuit board of the calendar body, and the metal shielding cover is fixedly mounted on the circuit board by a screw.

As a preferred solution of the present disclosure, an outer surface of the shell is provided with a first frosted texture, and an inner surface of the magnetic attraction plate is provided with a second frosted texture.

As a preferred solution of the present disclosure, the shell and the magnetic attraction plate are made of metal or nonmetal, and the magnetic back plate is made of metal that is capable of being magnetically attracted by the magnet.

As a preferred solution of the present disclosure, an outer ring of the magnet is coated with an elastic rubber ring, and groove walls in the first groove and the second groove are provided with annular grooves whose dimensions are adapted to the elastic rubber ring.

As a preferred solution of the present disclosure, an outer surface of the magnetic attraction plate is provided with a third groove, and a shape of the third groove is adapted to a shape of the magnetic back plate.

As a preferred solution of the present disclosure, a plurality of fourth grooves are provided on an inner side of the magnetic back plate, and a plurality of magnets located on an outer side are magnetically adsorbed with a plurality of magnets inside the second groove of the shell after being embedded in the fourth groove.

Compared with the prior art, the present disclosure has the following beneficial effects.

1) The multifunctional intelligent calendar provided by the present disclosure effectively solves the use limitation problem of the existing intelligent calendar through the arranged magnetic attraction mechanism. The detachable shell covering the back of the intelligent electronic calendar body cooperates with the magnetic attraction components located on an inner side and an outer side of the shell in the magnetic attraction mechanism, the magnetic attraction plate, and the magnetic back plate. In this way, the calendar is magnetically fixed, so that the calendar can be easily adsorbed on a surface such as a wall and a metal object, and can be stably fixed on an inclined surface, at a side-hanging position, or at a ceiling-mounted suspending position, which greatly expands use scenes of the intelligent calendar, meets the diverse needs of users such as viewing menus in a kitchen, recording to-do items in a bathroom or recording trips outdoors, and effectively ensures practical functionality of the intelligent calendar.

2) According to the multifunctional intelligent calendar provided by the present disclosure, the magnets are distributed in an array on the inner side and the outer side of the shell, so that users can select an appropriate number of magnets with an appropriate arrangement manner for mounting according to the actual fixing needs while ensuring the adsorption stability. However, the arranged metal shielding cover effectively avoids the interference of the magnetic attraction mechanism on the circuit board, and improves the reliability of a device. The frosted textures on the surfaces of the shell and the magnetic attraction plate not only enhance a friction to prevent the calendar from slipping, but also improve the texture and aesthetics of a product, so that the intelligent calendar of the present disclosure has functions of personalized placement and decoration on the basis of achieving inherent functions, which brings a better user experience to users.

### BRIEF DESCRIPTION OF THE DRAWINGS

FIG. 1 is a schematic structural diagram of the present disclosure;

FIG. 2 is one of schematic structural diagrams of the present disclosure;

FIG. 3 is a disassembly schematic diagram of the present disclosure;

FIG. 4 is one of disassembly schematic diagrams of the present disclosure;

FIG. 5 is a schematic structural diagram of Embodiment 2 of the present disclosure;

FIG. 6 is a schematic structural diagram of Embodiment 3 of the present disclosure;

FIG. 7 is a schematic structural diagram of Embodiment 4 of the present disclosure;

FIG. 8 is a schematic structural diagram of Embodiment 5 of the present disclosure;

FIG. 9 is a schematic structural diagram of Embodiment 6 of the present disclosure;

FIG. 10 is a schematic structural diagram of Embodiment 7 of the present disclosure; and

FIG. 11 is one of schematic structural diagrams of Embodiment 8 of the present disclosure.

In the figures: 100, calendar body; 110, shell; 111, second groove; 120, circuit board; 130, metal shielding cover; 140, first frosted texture; 200, magnetic attraction mechanism; 210, magnetic attraction component; 211, magnet; 220, magnetic attraction plate; 221, first groove; 222, second frosted texture; 230, magnetic back plate; 300, elastic rubber ring; 310, annular groove; 400, third groove; 500, fourth groove; 600, U-shaped frame; 610, clamping groove; 620, fixing lug; 630, double-sided adhesive plate; 700, magnetic plate; 710, fifth groove; 800, rotating support frame; 810, sixth groove; 820, spring pin; 830, pin hole.

### DETAILED DESCRIPTION OF THE EMBODIMENTS

In the following, the technical solution in the embodiments of the present disclosure will be clearly and completely described with reference to the attached drawings in the embodiments of the present disclosure. Obviously, the described embodiments are only some of the embodiments of the present disclosure, rather than all of the embodiments. Based on the embodiments in the present disclosure, all other embodiments obtained by those skilled in the art without paying creative labor belong to the scope of protection of the present disclosure.

### Embodiment 1

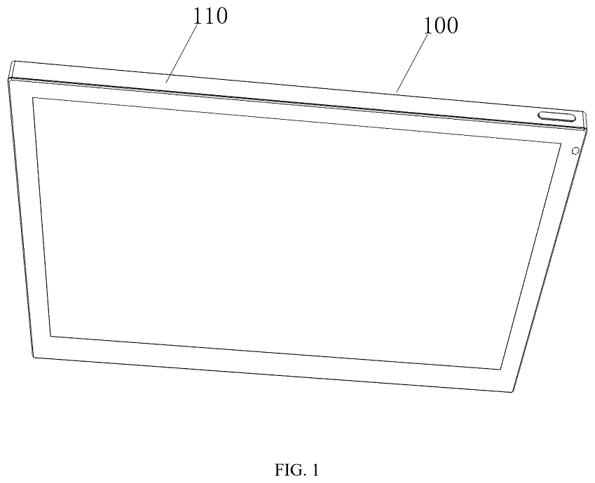

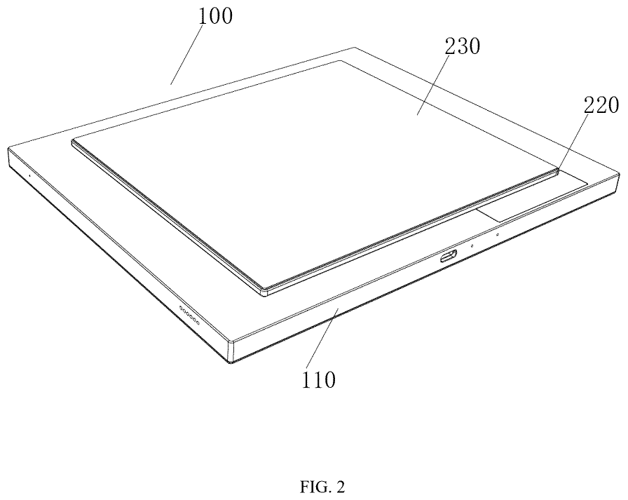

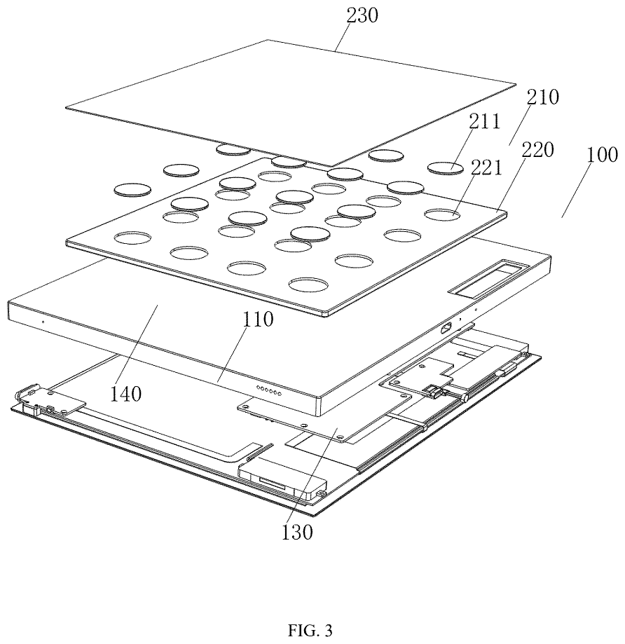

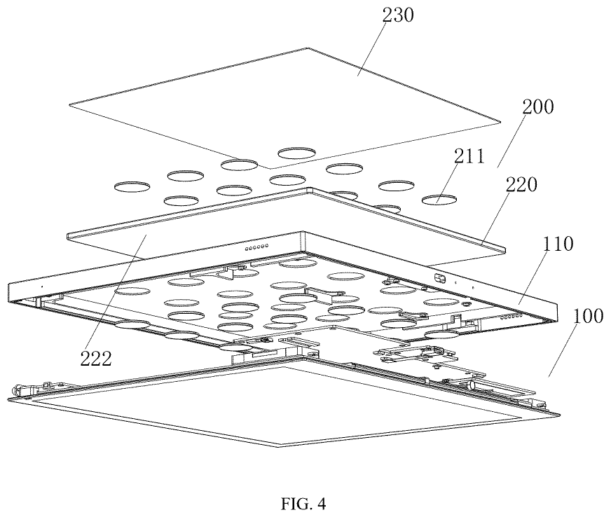

Refer to FIG. 1 to FIG. 4. The present disclosure provides a technical solution. A multifunctional intelligent calendar is provided, which includes an intelligent electronic calendar body 100 and a magnetic attraction mechanism 200. A detachable shell 110 covers the back of the intelligent electronic calendar body 100. The magnetic attraction mechanism 200 includes magnetic attraction components 210 located on an inner side and an outer side of the shell 110. The magnetic attraction component 210 magnetically attracts a magnetic attraction plate 220 located outside the shell 110. A magnetic back plate 230 is magnetically adsorbed on an outer side of the magnetic attraction plate 220. A calendar body 100 is suspended and fixed after the magnetic back plate 230 is adsorbed with a magnetic object or a metal object. Each layer of the magnetic attraction components 210 includes at least one magnet 211. The magnets 211 of two layers of the magnetic attraction components 210 are oppositely arranged in position and connected by magnetic non-contact adsorption. The magnets 211 located on an outer side are flush-embedded in a first groove 221 provided on the outer side of the magnetic attraction plate 220. The magnets 211 located on an inner side are flush-embedded in a second groove 111 provided on the inner side of the shell 110, and a position of the first groove 221 is opposite to that of the second groove 111.

Specifically, when users need to fix the intelligent calendar on a wall, the magnetic back plate 230 with adhesive backing can be first pasted on the wall, the magnetic attraction plate 220 is then close to the magnetic back plate 230, and the magnets 211 of the magnetic attraction components 210 on the inner side and the outer side of the shell are magnetically connected, so that the intelligent electronic calendar body 100 is stably suspended, which not only avoids punching holes in the wall, but also can flexibly adjust the calendar position to meet the use needs of different users in diverse scenes, For example, the calendar can be fixed on the side of a metal filing cabinet in an office, facilitating easy access to work schedules at any time.

The two layers of magnets 211 of the magnetic attraction components 210 are oppositely arranged in position, which ensures that the magnets 211 are uniformly stressed in an adsorption process, effectively improves the adsorption stability, and keeps stable even when there is water vapor on the wall.

When users need to change the calendar position, the magnetic attraction plate 220 and the magnetic back plate 230 only need to be separated in sequence, a new magnetic back plate 230 is re-mounted, and then the new magnetic back plate 230 is magnetically attracted with the magnetic attraction plate 220 again, thus improving the convenience of use.

In this embodiment, a plurality of magnets 211 of the magnetic attraction components 210 are distributed in a linear, triangular, rectangular, circular or polygonal array on the inner side and the outer side of the shell 110.

Specifically, a plurality of magnets 211 of the magnetic attraction component 210 are distributed in various arrays on the inner side and the outer side of the shell 110. Different array distribution manners can be adapted to different use scenes and adsorption requirements. When used outdoors, in the face of an external interference such as wind power, magnets 211 distributed in a triangular or rectangular array can form a stable triangular or rectangular stress structure through multi-point adsorption, so as to disperse an external force and prevent a calendar from falling. However, in the use of decoration of a wall of a living room in a family, distribution of a circular or polygonal array can be selected, which not only ensures the adsorption force, but also increases the aesthetics.

In this embodiment, the magnet 211 is one or more of a triangle, a circle, a rectangle or a polygon, and a thickness of the magnet 211 is the same as groove depths in the first groove 221 and the second groove 111.

Specifically, in the ceiling-mounted suspending use scene, the circular magnet 211 can effectively disperse the gravity due to its characteristics of having no edges and corners and having a uniform stress, and prevent the calendar from falling due to an excessive local stress. However, the rectangular magnet 211 can enhance lateral stability through an adsorption force in a long side direction when it is placed at a side-hanging position. At the same time, the thickness of the magnet 211 is the same as the groove depths in the first groove 221 and the second groove 111. After the magnet is mounted, the surface of the magnet is flush with the plane where the groove is located, which not only ensures tightness of magnetic attraction, but also avoids collision damage resulted from protrusion of the magnet.

In this embodiment, a metal shielding cover 130 is arranged on the inner side of the shell 110 at a position opposite to a circuit board 120 of the calendar body 100, and the metal shielding cover 130 is fixedly mounted on the circuit board 120 by a screw.

Specifically, during the operation of the intelligent calendar, the magnetic field generated by the magnet 211 may interfere with the normal operation of the circuit board 120, resulting in issues such as delayed schedule reminders or data reading errors. However, the metal shielding cover 130 blocks the magnetic field interference from the circuit board 120 by an electrostatic shielding principle, ensuring the stable operation of electronic components. Alternatively, in the vehicle-mounted use scene, there are many metal parts with a complex magnetic field environment. The metal shielding cover 130 can effectively resist external magnetic field interference, ensuring that the calendar accurately records trips and reminders in a driving process, and providing users with a reliable user experience.

In this embodiment, an outer surface of the shell 110 is provided with a first frosted texture 140, and an inner surface of the magnetic attraction plate 220 is provided with a second frosted texture 222.

Specifically, in the kitchen cooking scene, users may have water stains or oil stains on their hands. The first frosted texture 140 and the second frosted texture 222 which are arranged increase a surface friction, so that the calendar is not prone to slipping due to hand contact during adsorption. At the same time, the frosted texture can effectively improve the appearance grade of products. Users can select the shell 110 and the magnetic attraction plate 220 in different colors and textures according to their home decoration style for matching, achieving a personalized decorative effect. In addition, the frosted texture can also reduce the retention of fingerprints and the appearance of scratches on the surface, keeping the appearance of the calendar clean and beautiful, and prolonging the service life of the product.

In this embodiment, the shell 110 and the magnetic attraction plate 220 are made of metal or nonmetal, and the magnetic back plate 230 is made of metal that is capable of being magnetically attracted by the magnet 211.

Specifically, when the calendar is carried outdoors, the shell 110 and the magnetic attraction plate 220 made of nonmetal are selected, which effectively reduces the overall weight so that it is convenient for users to carry. When the calendar is used in a scene with high requirements for adsorption strength, the shell 110 and the magnetic attraction plate 220 made of metal are selected, which can enhance the overall structural strength and the adsorption force. In addition, the metal material of the magnetic back plate 230 ensures that the magnetic back plate can be stably adsorbed with the magnet 211, which can effectively guarantee the reliable fixation and use of the intelligent calendar in home, office or industrial environments.

### Embodiment 2

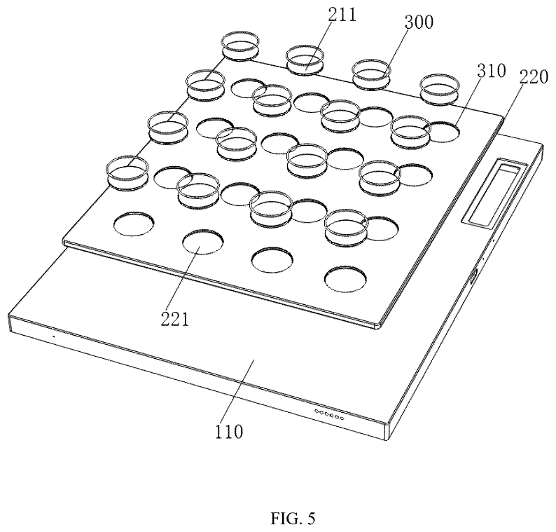

Refer to FIG. 5. The technical feature that distinguishes this embodiment from Embodiment 1 is that an outer ring of the magnet 211 is coated with an elastic rubber ring 300, and groove walls in the first groove 221 and the second groove 111 are provided with annular grooves 310 whose dimensions are adapted to the elastic rubber ring 300.

Specifically, when users adsorb the intelligent electronic calendar body 100 to the magnetic attraction plate 220, the elastic rubber ring 300 can buffer the impact force of the magnet 211 at the moment of contact, so as to prevent the magnet 211 or the groove from being damaged due to collision. However, in the use scene with strong vibration, for example, when being mounted on a dashboard of an automobile, the elastic rubber ring 300 absorbs the vibration energy in the driving process of the vehicle through its own elastic deformation, thus reducing the influence on a magnetic attraction connection structure, and preventing the calendar from loosening and falling due to vibration. At the same time, the rubber ring 300 can also play a sealing role, prevent dust and water vapor from entering the groove, protect the magnet 211 from being oxidized, prolong the service life of the magnetic attraction mechanism, and ensure the long-term stable use of the calendar.

### Embodiment 3

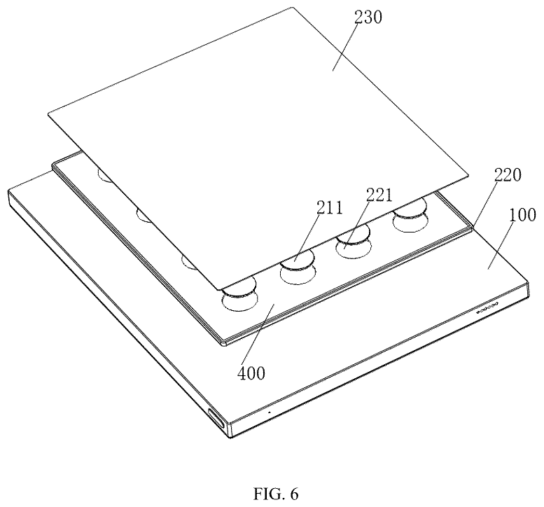

Refer to FIG. 6. An outer surface of the magnetic attraction plate 220 is provided with a third groove 400, and a shape of the third groove 400 is adapted to a shape of the magnetic back plate 230.

Specifically, when the intelligent calendar is mounted, users can accurately embed the magnetic back plate 230 into the third groove 400, thus achieving quick alignment and avoiding insecure adsorption resulted from position deviation.

### Embodiment 4

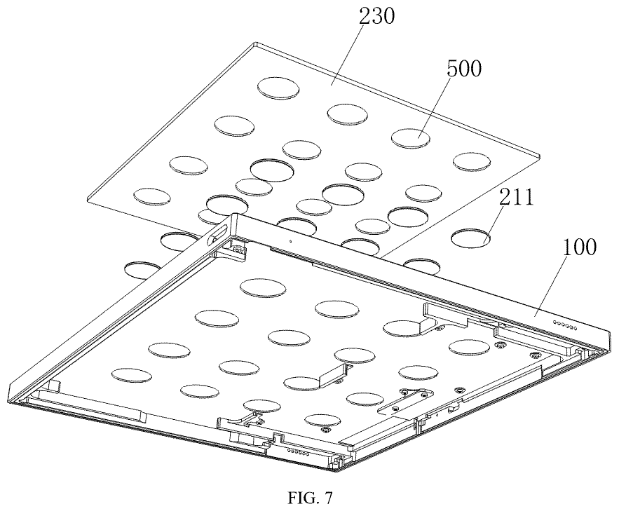

Refer to FIG. 7. A plurality of fourth grooves 500 are provided on an inner side of the magnetic back plate 230, and a plurality of magnets 211 located on an outer side are magnetically adsorbed with a plurality of magnets 211 inside the second groove 111 of the shell 110 after being embedded in the fourth groove 500.

Specifically, when the calendar needs to be fixed on a surface of a heavy metal refrigerator, the magnet 211 on the outer side is embedded in the fourth groove 500, so that a distance between two layers of magnets 211 is closer without adding the magnetic attraction plate 220, which effectively improves the adsorption strength between the two layers of magnets 211, ensures the accuracy and stability of magnetic attraction connection, and also facilitates disassembly and reinstallation by users to improve use flexibility.

### Embodiment 5

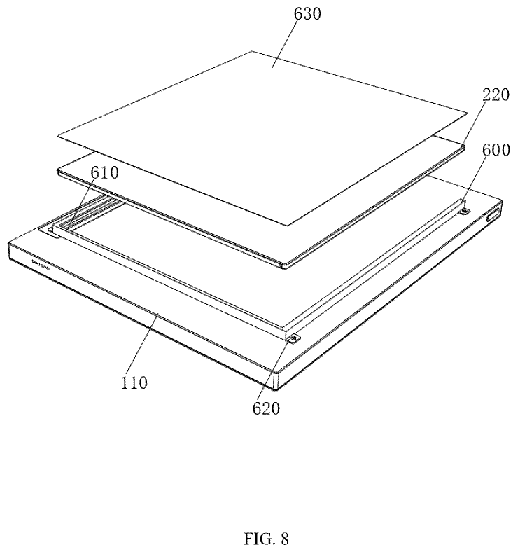

Refer to FIG. 8. The technical feature that distinguishes this embodiment from Embodiment 1 is that a U-shaped frame 600 is arranged on the outer side of the shell 110. A clamping groove 610 is provided on the inner side of the U-shaped frame 600. A fixing lug 620 arranged by the U-shaped frame 600 is detachably connected with the shell 110 through a screw. The magnetic attraction plate 220 can be flexibly inserted into the clamping groove 610, and the outer side of the magnetic attraction plate 220 is bonded to and fixed with a fixing surface through a double-sided adhesive plate 630. Moreover, the dimension of the double-sided adhesive plate 630 is smaller than that of the magnetic attraction plate 220.

Specifically, when users need to mount intelligent calendars on some surfaces that are not suitable for direct magnetic attraction fixation, such as wooden walls, the double-sided adhesive plate 630 can be first pasted on a fixing surface, and then the outer side of the magnetic attraction plate 220 is bonded to the double-sided adhesive plate 630. Because the dimension of the double-sided adhesive plate 630 is smaller than that of the magnetic attraction plate 220, the edge of the magnetic attraction plate 220 will be partially uncovered by the double-sided adhesive after the outer side of the magnetic attraction plate is bonded to the double-sided adhesive plate, which is convenient for subsequent operations. Thereafter, the U-shaped frame 600 on the shell 110 with the magnetic attraction plate 220 is aligned, so that the magnetic attraction plate 220 is inserted into the clamping groove 610 of the U-shaped frame 600. Preliminary fixation is achieved through the cooperation between the clamping groove 610 and the magnetic attraction plate 220. Thereafter, the magnets 211 of the magnetic attraction component 210 between the magnetic attraction plate 220 and the shell 110 attract each other, thereby further enhancing the fixing effect. In this way, the calendar can be fixed on a nonmagnetic surface, and the U-shaped frame 600 is detachably connected with the shell 110 through a screw, which is convenient for users to replace U-shaped frames or magnetic attraction plates with different specifications according to actual needs to be adapted to different mounting scenes and fixing requirements.

### Embodiment 6

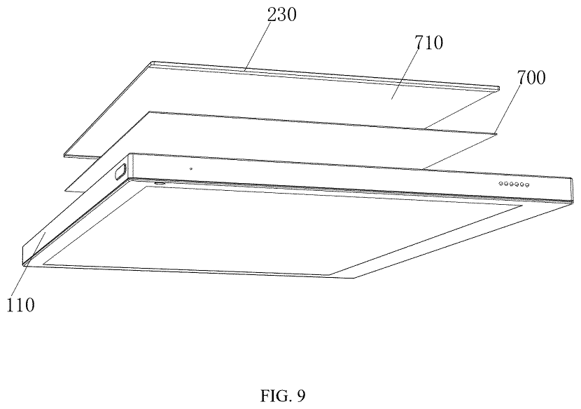

Refer to FIG. 9. The technical feature that distinguishes this embodiment from Embodiment 1 is that the magnet 211 of the magnetic attraction plate 220 is replaced with a magnetic plate 700, and the magnetic plate 700 is fixedly embedded in the fifth groove 710 provided in the magnetic back plate 230.

Specifically, in some scenes that require high adsorption stability and pursues structural simplicity, the magnet 211 of the magnetic attraction plate 220 is replaced with the magnetic plate 700. The magnetic plate 700 has stronger magnetism and a larger adsorption area. In a mounting process, the magnetic back plate 230 fixed with the magnetic plate 700 gets close to the shell 110, and the magnetic plate 700 and the magnetic attraction component 210 on the inner side of the shell 110 generate strong magnetic attraction, so that the calendar body 100 is firmly adsorbed. The magnetic plate 700 is embedded in the fifth groove 710 of the magnetic back plate 230, which, on the one hand, can effectively protect the magnetic plate 700 from being damaged by collision in a mounting and using process. On the other hand, an embedded structure allows the overall appearance to be more flat and beautiful, reduces convex parts, and reduces the risk of accidental collision.

For example, when an intelligent calendar is mounted on a metal whiteboard in a conference room, a strong adsorption force of the magnetic plate 700 can ensure that the calendar is always stable in the process of frequent use of the whiteboard, and may not fall due to shaking or touching of the whiteboard. At the same time, the flat appearance may not affect an overall visual effect of the whiteboard.

### Embodiment 7

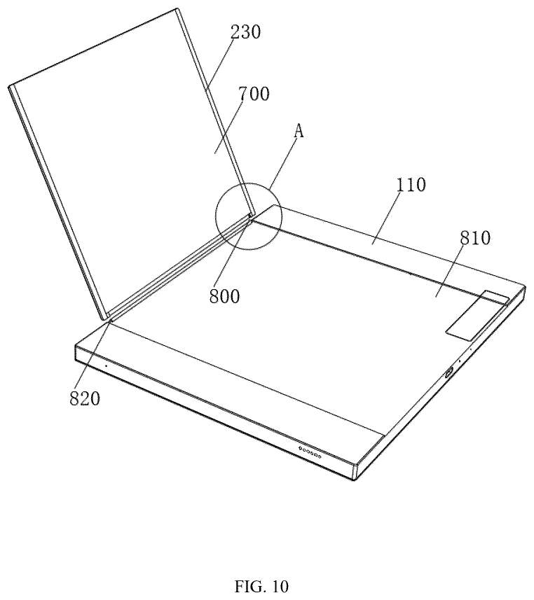

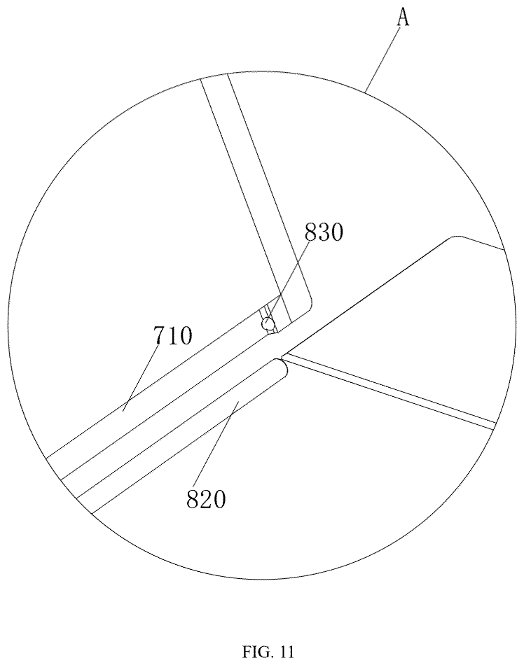

Refer to FIG. 10 and FIG. 11. This embodiment is based on Embodiment 6. The magnetic back plate 230 is rotatably connected with the shell 110 through a rotating support frame 800. The rotating support frame 800 includes a sixth groove 810 provided on the outer side of the shell 110. A spring pin 820 is mounted at one end of the sixth groove 810. The spring pin 820 is accommodated at one end of the fifth groove 710, and an inner side at one end of the fifth groove 710 is rotatably connected with the spring pin 820 through a pin hole 830 which is provided.

Specifically, when users use the intelligent calendar, it may be necessary to adjust the angle of the calendar according to their own viewing angle or a space situation of a mounting position. At this time, the advantage that the magnetic back plate 230 is rotatably connected with the shell 110 through the rotating support frame 800 is shown. The spring pin 820 is accommodated in the fifth groove 710 and cooperates with the pin hole 830, so that the magnetic back plate 230 can rotate with respect to the shell 110 with the spring pin 820 as an axis. When adjusting the angle, users only need to gently rotate the calendar body 100, and the spring pin 820 rotates in the pin hole 830 to drive the magnetic back plate 230 to change the angle. After being adjusted to a proper position, the spring pin 820 keeps stable cooperation with the pin hole 830 under the action of the spring, so that the calendar is fixed at this angle.

For example, in a family kitchen, the intelligent calendar is absorbed to a side of a refrigerator, so that users can adjust the angle of the calendar at any time according to their own standing position and line of sight direction during cooking, which is convenient to view the menu or schedule without disassembly and reinstallation. This significantly improves the convenience and flexibility of use, meeting the diverse needs of users.

What is not described in detail in this description belongs to the prior art known to those skilled in the art. Although the present disclosure has been described in detail with reference to the foregoing embodiments, it is still possible for those skilled in the art to modify the technical solutions described in the foregoing embodiments or replace some technical features by equivalents. Any modification, equivalent replacement, improvement, etc. made within the spirit and principle of the present disclosure should be included in the scope of protection of the present disclosure.

What is claimed is:

1. A multifunctional intelligent calendar, comprising: an intelligent electronic calendar body (100), wherein a detachable shell (110) covers the back of the intelligent electronic calendar body (100);
a magnetic attraction mechanism (200), wherein the magnetic attraction mechanism (200) comprises magnetic attraction components (210) located on an inner side and an outer side of the shell (110), the magnetic attraction component (210) magnetically attracts a magnetic attraction plate (220) located outside the shell (110), a magnetic back plate (230) is magnetically adsorbed on an outer side of the magnetic attraction plate (220), and a calendar body (100) is suspended and fixed after the magnetic back plate (230) is adsorbed with a magnetic object or a metal object;
each layer of the magnetic attraction components (210) comprises at least one magnet (211), the magnets (211) of two layers of the magnetic attraction components (210) are oppositely arranged in position and connected by magnetic non-contact adsorption, and the magnets (211) located on an outer side are flush-embedded in a first groove (221) provided on the outer side of the magnetic attraction plate (220).

2. The multifunctional intelligent calendar according to claim 1, wherein the magnets (211) located on an inner side are flush-embedded in a second groove (111) provided on the inner side of the shell (110), and a position of the first groove (221) is opposite to that of the second groove (111).

3. The multifunctional intelligent calendar according to claim 1, wherein a plurality of magnets (211) of the magnetic attraction components (210) are distributed in a linear, triangular, rectangular, circular or polygonal array on the inner side and the outer side of the shell (110).

4. The multifunctional intelligent calendar according to claim 1, wherein the magnet (211) is one or more of a triangle, a circle, a rectangle or a polygon, and a thickness of the magnet (211) is the same as groove depths in the first groove (221) and the second groove (111).

5. The multifunctional intelligent calendar according to claim 1, wherein a metal shielding cover (130) is arranged on the inner side of the shell (110) at a position opposite to a circuit board (120) of the calendar body (100), and the metal shielding cover (130) is fixedly mounted on the circuit board (120) by a screw.

6. The multifunctional intelligent calendar according to claim 1, wherein an outer surface of the shell (110) is provided with a first frosted texture (140), and an inner surface of the magnetic attraction plate (220) is provided with a second frosted texture (222).

7. The multifunctional intelligent calendar according to claim 1, wherein the shell (110) and the magnetic attraction plate (220) are made of metal or nonmetal, and the magnetic back plate (230) is made of metal that is capable of being magnetically attracted by the magnet (211).

8. The multifunctional intelligent calendar according to claim 1, wherein an outer ring of the magnet (211) is coated with an elastic rubber ring (300), and groove walls in the first groove (221) and the second groove (111) are provided with annular grooves (310) whose dimensions are adapted to the elastic rubber ring (300).

9. The multifunctional intelligent calendar according to claim 1, wherein an outer surface of the magnetic attraction plate (220) is provided with a third groove (400), and a shape of the third groove (400) is adapted to a shape of the magnetic back plate (230).

10. The multifunctional intelligent calendar according to claim 1, wherein a plurality of fourth grooves (500) are provided on an inner side of the magnetic back plate (230), and a plurality of magnets (211) located on an outer side are magnetically adsorbed with a plurality of magnets (211) inside the second groove (111) of the shell (110) after being embedded in the fourth groove (500).
